(19) United States
(12) Patent Application Publication
(10) Pub. No.: US 2025/0055241 A1
(43) Pub. Date: Feb. 13, 2025

(54) PULSE STRETCHER SYSTEM AND METHOD

(71) Applicant: Applied Materials Israel Ltd., Nes Ziona (IL)

(72) Inventors: Ron NAFTALI, Shoham (IL); Haim FELDMAN, Nof-Ayalon (IL); Boris GOLBERG, Ashdod (IL); Ram ORON, Nes Ziona (IL)

(21) Appl. No.: 18/231,221

(22) Filed: Aug. 7, 2023

(51) Int. Cl. H01S 3/00

(52) U.S. Cl. CPC H01S 3/0057

(57) ABSTRACT

A pulse stretcher unit, and a respecting inspection system are disclosed. The pulse stretcher unit comprises a selected number of beam splitters arranged along a selected main path and comprising an input beam splitter, an output beam splitter and one or more intermediate beam splitters, and an arrangement of light reflecting surfaces defining a selected number of n auxiliary paths extending between said selected number of beam splitters. Wherein said selected number of beam splitters direct input beam between said selected main path and said selected number of auxiliary paths for splitting an input pulse into a series of pulses having generally equal amplitude. And wherein lengths of said auxiliary paths follow approximately a series of the form L/2^{k} for k=0, 1, 2, where L is a selected length of an auxiliary path.

### TECHNOLOGICAL FIELD

The present disclosure relates to manipulation of electromagnetic radiation pulses and specifically relates to techniques for stretching pulses into a plurality of similar pulses.

### BACKGROUND

Short laser pulses provide high instantaneous amplitude with relatively low average power. As such, short laser pulses are often used in applications digging into nonlinear interactions in light. #

U.S. Pat. No. 5,309,456 provides an apparatus (20) for increasing the length of a laser pulse to reduce its peak power without substantial loss in the average power of the pulse. The apparatus (20) uses a White cell (10) having a plurality of optical delay paths (18a-18d) of successively increasing number of passes between the field mirror (13) and the objective mirrors (11 and 12). A pulse (26) from a laser (27) travels through a multi-leg reflective path (28) between a beam splitter (21) and a totally reflective mirror (24) to the laser output (37). The laser pulse (26) is also simultaneously injected through the beam splitter (21) to the input mirrors (14a-14d) of the optical delay paths (18a-18d). The pulses from the output mirrors (16a-16d) of the optical delay paths (18a-18d) go simultaneously to the laser output (37) and to the input mirrors (14b-14d) of the longer optical delay paths. The beam splitter (21) is 50% reflective and 50% transmissive to provide equal attenuation of all of the pulses at the laser output (37).

U.S. Pat. No. 5,337,333 describes a method for formatting a laser beam pulse (20) using one or more delay loops (10). The delay loops (10) have a partially reflective beam splitter (12) and a plurality of highly reflective mirrors (14) arranged such that the laser beam pulse (20) enters into the delay loop (10) through the beam splitter (12) and circulates therein along a delay loop length (24) defined by the mirrors (14). As the laser beam pulse (20) circulates within the delay loop (10) a portion thereof is emitted upon each completed circuit when the laser beam pulse (20) strikes the beam splitter (12). The laser beam pulse (20) is thereby formatted into a plurality of sub-pulses (50, 52, 54 and 56). The delay loops (10) are used in combination to produce complex waveforms by combining the sub-pulses (50, 52, 54 and 56) using additive waveform synthesis.

U.S. Pat. No. 7,567,343 describes that as circuit patterns become finer in recent years, improvement in detection sensitivity of defects is required. To answer this, sensitivity is being enhanced using a laser with a wavelength of the UV band as the laser for irradiation. A pulse oscillation laser is often used as the UV laser. However, a peak (maximum output) of the pulse oscillation laser becomes very large to an average output power required. For example, in the case of a laser of average output power 2 W, pulse interval 10 ns, and pulse width 10 ps, the peak (maximum output) becomes as high as 2 kW, and there is the possibility of causing a damage to a sample. Therefore, it is necessary to reduce the peak (maximum output) with the average output power being maintained, so that it may not cause a damage to the sample. In this invention, the device is configured in such a way that pulsed light is optically divided into several pulses and these pulses are given respective paths whose lengths are set different from one another, whereby the peak (maximum output) is reduced while the average output value is maintained. #

### GENERAL DESCRIPTION

Laser illumination provides efficient and high intensity illumination of a selected wavelength range. Laser illumination typically provides various advantages over other light sources by enabling selected spatial and/or temporal coherence to output light. Accordingly, the use of laser illumination, and specifically pulses laser illumination, provides various advantages in illumination applications.

Pulsed laser illumination provides relatively high instantaneous illumination intensity, while utilizing relatively low average power over time. However, some applications may require increased pulse duration, and tailoring of length and amplitude of illumination pulses.

The present disclosure provides a pulse stretcher unit suitable for manipulating an input illumination pulsed beam, to generate an output beam formed by a pulse train, comprising a selected number of illumination pulses having generally equal pulse amplitude. The pulse stretcher of the present disclosure is configured to increase temporal and/or longitudinal length of output pulse, enabling increase in pulse etendue and enable reduced pulse temporal coherence.

The present disclosure provides a pulse stretcher unit formed of a plurality of beam splitters configured to receive an input beam and split the input beam to propagate both along a selected general propagation axis and along a selected number of auxiliary paths defined by an arrangement of reflective surfaces. The arrangement of beam splitter directed light portions toward a selected number of auxiliary paths having optical lengths selected in accordance with a predetermined length ratios providing selected separation between sub-pulses of the output beam, to provide an output beam carrying a pulse sequence formed of a selected number of pulses having generally equal pulse amplitude.

The pulse stretcher may be configured to selectively vary spatial arrangement of the output beam, thereby enabling increased etendue of the output beam. It may be used for adjusting selected illumination conditions for use in aerial illumination and aerial inspection/imaging of semiconductor wafer having a selected pattern and/or in inspection/imaging of selected mask patterns for use in photolithography or other manufacturing processes.

Thus, according to a broad aspect, the present disclosure provides a pulse stretcher unit comprising:
a selected number of beam splitters arranged along a selected main path and comprising an input beam splitter, an output beam splitter and one or more intermediate beam splitters, and an arrangement of light reflecting surfaces defining a selected number of n auxiliary paths extending between said selected number of beam splitters; wherein
   (a) said input beam splitter is configured to receive an input beam and to direct a first portion of the beam along said selected main path and a second portion of the beam along a first auxiliary path;
   (b) said output beam splitter is configured to receive first input beam portion propagating along said selected main path and a second input beam portion propagating along an n'th auxiliary path, and to provide at least one output beam propagating along said selected main path; and
   (c) each one or more intermediate beams splitters is configured to receive a first input beam portion propagating along said selected main path and a second input beam portion propagating along an i'th auxiliary path, and to provide a first portion of output beam propagating along said selected main path and a second portion of output beam propagating along a respective i+1 auxiliary path; and wherein
   lengths of said auxiliary paths follow approximately a series of the form L/2^{k} for k=0, 1, 2, where L is a selected length of an auxiliary path.

Generally, the one before last beam splitter may direct second beam portion to propagate along the nth auxiliary path.

According to some embodiments, the lengths of said auxiliary paths follow the form L/2^{k} for k=0, 1, 2, where L is a selected length of an auxiliary path up to 25% length variation. In some embodiments, the lengths of the auxiliary paths may vary by up to 10% from the form L/2^{k} for k=0, 1, 2, where L is a selected length of an auxiliary path. in some embodiments, the allowed variation is up to 5%.

According to some embodiments, length of said auxiliary path may be larger than length of portion of said selected main path between consecutive beam splitters. For example, length of portion of said selected main path between consecutive beam splitters may be of the order of 1-50 centimeters, and length of auxiliary paths may vary between 0.5 meter and 10 meters.

According to some embodiments, the pulse stretcher unit may further comprise an output reflecting surface, wherein said output beam splitter provides a portion of output beam to propagate along said selected main path and a second portion of output beam to propagate along an output auxiliary path, said output reflecting surface is positioned to direct said second portion of output beam to propagate along a selected auxiliary output path.

According to some embodiments, the selected number of beam splitters comprise one or more beam splitters mounted on a moveable platform, moveable along at least one axis perpendicular to said selected main path, enabling output beam in the form of two parallel output beams.

According to some embodiments, the output beam splitter is mounted on a moveable platform, moveable along at least one axis perpendicular to said selected main path, enabling output beam in the form of two parallel output beams.

According to some embodiments, the arrangement of light reflecting surfaces comprise a selected number of curved reflective surfaces configured to focus beam impinging thereof to maintain at least one of beam divergence angle and beam width.

According to some embodiments, the selected number of beam splitters consists of polarization independent beam splitters.

According to some embodiments, the input beam splitter may be a polarization beam splitter and said output beam splitter and one or more intermediate beam splitters are polarization independent beam splitters.

According to some embodiments, the pulse stretcher unit may further comprise one or more polarization rotation plates positioned in said selected main path between said input beam splitter and a consecutive beam splitter.

According to some embodiments, the pulse stretcher unit may further comprise a polarization rotation plate positioned in said auxiliary path between said input beam splitter and a consecutive beam splitter.

According to some embodiments, the selected number of beam splitters comprise polarization independent beam splitters.

According to some embodiments, the selected number of beam splitters comprises or consists of beam splitter configured to split input beams with a power ratio between 0.4:0.6 and 0.6:0.4.

According to some embodiments, the arrangement of beam splitter define one or more auxiliary paths and wherein said one or more auxiliary paths are being folded by one or more reflecting surfaces arranged to cause radiation to be reflected back and front between the reflective surfaces through the auxiliary path.

According to some embodiments, at least one auxiliary path comprises, or being formed of, a plurality of spherical mirrors and a common flat mirror arranged such that radiation beam is reflected between said spherical mirrors and said flat mirror for a selected number of times.

According to some embodiments, the pulse stretcher unit may be operable in ultraviolet wavelength range.

According to one other broad aspect, the present disclosure provides a pulse stretching system comprising at least one first pulse stretcher unit and at least one second pulse stretcher unit; said at least one first pulse stretcher unit comprises:
a selected number of beam splitters arranged along a selected main path and comprising an input beam splitter, an output beam splitter and one or more intermediate beam splitters, and
an arrangement of light reflecting surfaces defining a selected number of n auxiliary paths extending between said selected number of beam splitters; wherein
   (a) said input beam splitter is configured to receive an input beam and to direct a first portion of the beam along said selected main path and a second portion of the beam along a first auxiliary path;
   (b) said output beam splitter is configured to receive first input beam portion propagating along said selected main path and a second input beam portion propagating along an n'th auxiliary path, and to provide at least one output beam propagating along said selected main path; and
   (c) each one or more intermediate beams splitters is configured to receive a first input beam portion propagating along said selected main path and a second input beam portion propagating along an i'th auxiliary path, and to provide a first portion of output beam propagating along said selected main path and a second portion of output beam propagating along a respective i+1 auxiliary path; wherein
      lengths of said auxiliary paths follow approximately a series of the form L/2^{k} for k=0, 1, 2, where L is a selected length of an auxiliary path; and wherein
      said at least one second pulse stretcher unit is placed downstream of said at least one first pulse stretcher unit, such that output beam of said at least one first pulse stretcher unit is input beam to said at least one second pulse stretcher unit.

The term approximately relates to length variations of up to 25%, or up to 10% or up to 5%.

According to some embodiments, the at least one second pulse stretcher may be configured to stretch input beam at least partially in spatial domain.

According to some embodiments, the pulse stretcher unit may be configured using any one or the variations or embodiments described herein.

According to yet another broad aspect, the present disclosure provides an inspection system comprising a light source unit, a pulse stretcher unit, and a collection unit for collecting illumination signal from a sample, wherein said pulse stretcher unit is configured to receive input illumination beam from said light source unit and to split one or more pulses of said input illumination beam into a plurality of pulses having selected temporal separation between them and having substantially equal amplitude, and to direct output beam comprising said plurality of pulses to illuminate the sample.

According to some embodiments, the pulse stretcher unit comprises a selected number of beam splitters arranged along a selected main path and comprising an input beam splitter, an output beam splitter and one or more intermediate beam splitters, and
an arrangement of light reflecting surfaces defining a selected number of n auxiliary paths extending between said selected number of beam splitters; wherein
   (a) said input beam splitter is configured to receive an input beam and to direct a first portion of the beam along said selected main path and a second portion of the beam along a first auxiliary path;
   (b) said output beam splitter is configured to receive first input beam portion propagating along said selected main path and a second input beam portion propagating along an n'th auxiliary path, and to provide at least one output beam propagating along said selected main path; and
   (c) each one or more intermediate beams splitters is configured to receive a first input beam portion propagating along said selected main path and a second input beam portion propagating along an i'th auxiliary path, and to provide a first portion of output beam propagating along said selected main path and a second portion of output beam propagating along a respective i+1 auxiliary path; wherein
      lengths of said auxiliary paths follow approximately a series of the form L/2^{k} for k=0, 1, 2, where L is a selected length of an auxiliary path.

The term approximately relates to length variations of up to 25%, or up to 10% or up to 5%.

According to some embodiments, the at least one second pulse stretcher may be configured to stretch input beam at least partially in spatial domain.

According to some embodiments, the pulse stretcher unit may be configured using any one or the variations or embodiments described herein.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 schematically illustrates a pulse stretcher unit according to some embodiments of the present disclosure;

FIG. 2 exemplifies an additional configuration of a pulse stretcher unit according to some embodiments of the present disclosure;

FIG. 3 exemplifies a further configuration of a pulse stretcher unit utilizing a polarization rotator according to some embodiments of the present disclosure;

FIG. 4 illustrates a pulse stretcher unit utilizing a moveable output beam splitter according to some embodiments of the present disclosure;

FIG. 5 illustrates output pulse sequence and formation of the pulse sequence within the pulse stretcher according to some embodiments of the present disclosure;

FIG. 6 illustrates a pulse stretcher configuration utilizing a common reflective surface for a plurality of auxiliary paths according to some embodiments of the present disclosure;

FIG. 7 exemplifies a concatenated pulse stretcher arrangement according to some embodiments of the present disclosure; and

FIG. 8 exemplifies an inspection system utilizing a pulse stretcher unit according to some embodiments of the present disclosure.

### DETAILED DESCRIPTION OF EMBODIMENTS

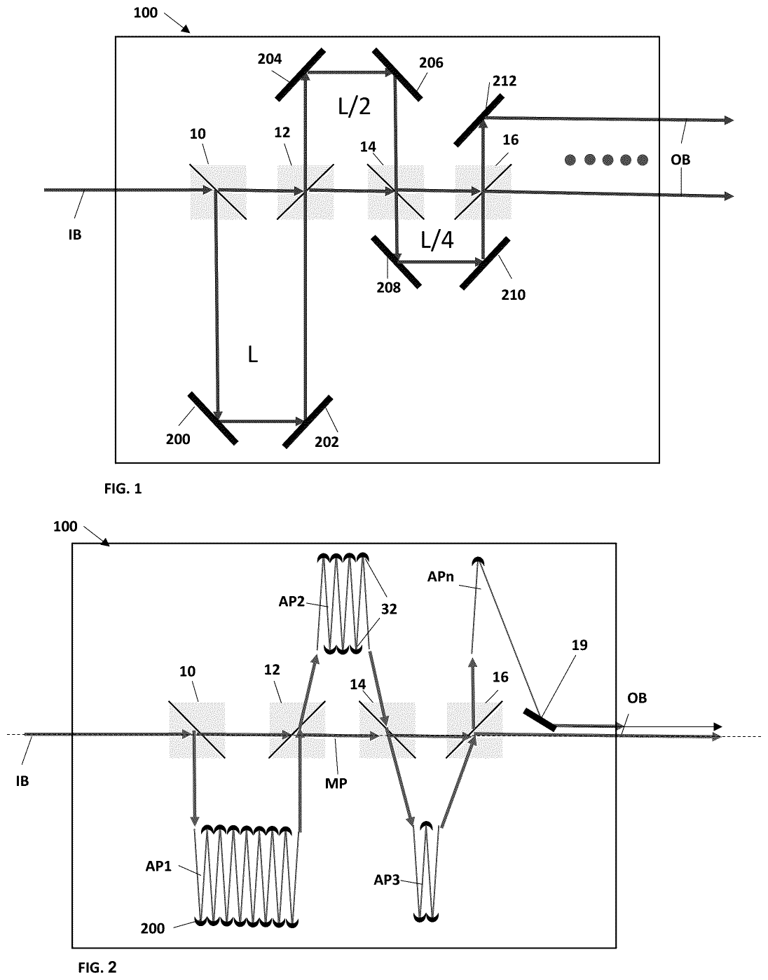

As indicated above, the present disclosure provides a pulse stretcher unit configured for receiving an input radiation beam formed by one or more short pulses, and for stretching the one or more short pulses to provide output beam including a plurality of radiation pulses having generally equal amplitude between them. Reference is made to FIG. 1 illustrating schematically a pulse stretcher unit 100 according to some embodiments of the present disclosure. System 100 includes a selected number of beam splitter units including in this example beam splitters 10, 12, 14, and 16, and an arrangement of reflecting surfaces 200 to 212 in this example. The beam splitters 10 to 16 include an input beam splitter 10, output beam splitter 16 and one or more intermediate beam splitters (12 and 14 in this example). The beam splitters 10 to 16 are configured to direct an input radiation beam along a main path through the pulse stretcher unit. Additionally, each beams splitter is configured to direct a portion of input beam received thereby along a respective auxiliary path. Accordingly, the pulse stretcher unit 100 defines a main path for beam propagation, and a selected number N−1 of auxiliary path, defined by a number N of beam splitters used in the pulse stretcher.

To align the output pulses and provide output beam having a series of pulses having equal amplitude and spacing between them. The optical paths of the auxiliary paths follow a selected condition such that a longest auxiliary path has length L, second longest auxiliary path has length L/2, the next auxiliary path has length L/4, L/8 and so on. Generally, lengths of the auxiliary paths are defined as L/2^{k} for k=[0, 1, 2 . . . ]. Is should be noted that the optical path/length of the auxiliary paths may be approximate, and that variation of up to 25%, or up to 10%, or up to 5% may be suitable.

The beam splitters 10 to 16 are generally configured as 50/50 beam splitters providing that each input pulse is divided into two output beam portions propagating one along the main path, and one along the respective auxiliary path. This configuration provides that each pulse is split into two pulse portions of generally equal intensity. Additionally, optical path length differences between the auxiliary paths, and the distance between beam splitters 10 to 16 along the main path may generally be selected to prevent temporal overlap between split pulses, separating an input pulse into a pulse train, having generally equal distance between pulses. Further, the beam splitters may typically be polarization independent beam splitters, splitting input beam into first and second beam portions independent of polarization components of the beams. Generally, if lengths of the auxiliary paths vary from the desired length relations, output beam may result in variation in delay between the pulse portions thereof. This may be advantageous in some applications, where accurate delay between pulse portions is not needed.

To maintain form factor of the pulse stretcher unit 100, the selected number of auxiliary paths may be folded using a selected number of reflective surfaces. This is illustrated in FIG. 2 schematically exemplifying an additional configuration of the pulse stretcher 100 according to some embodiments of the present disclosure. In this example, system 100 is exemplifies with an arrangement of reflecting surfaces, generally at 200, defining a selected number of auxiliary paths for radiation propagation. Accordingly, a first input beam splitter 10 is positioned to receive input beam IB and split the input beam into a first portion propagating along the main path MP of the pulse stretcher unit 100, and into a second portion propagating along the first auxiliary path AP1. Second beam splitter 12 is configured to receive a first input beam arriving along the main path MP and split it into a first portion propagating along the main path, and a second portion propagating along the second auxiliary path AP2. Additionally, the second beam splitter is configured to receive a second input beam arriving from the first auxiliary path, and to split the second input beam into a first portion propagating along the main path MP, and a second portion propagating along the second auxiliary path AP2. Generally, the n'th beam splitter of the pulse stretcher 100 received a first input beam portion arriving along the main path and directs it to first and second beams propagating along the main path and the n'th auxiliar path and received a second input beam portion arriving along the n−1 auxiliar path directed to first and second beams propagating along the main path and the n'th auxiliar path.

The last beam splitter 16 of the pulse stretcher unit 100 receives first input beam portion arriving along the main path, and a second input beam portion arriving along an auxiliary path and splits each input beam portion into a first output beam portion propagating along the main path MP, and a second output beam portion propagating along an auxiliary output path APn. The output beam splitter 16 is generally used to combine the beam portions propagating along the main and respective auxiliary path. Accordingly, beam splitter 16 may include a layered structure that prevents light transmission through the beam splitter toward final auxiliary path APn, and allow light to propagate only along the main path to provide single output beam OB.

In some other embodiments, the output beam splitter 16 is a 50/50 beam splitter directing a portion of light toward auxiliary path APn. In these embodiments, auxiliary path APn includes one or more light directing optical elements directing light along the path to provide a second portion of output beam, typically aligned to be parallel to the first output beam. For example, light deflecting element 19 may be positioned to align light components propagating along auxiliary path APn to be parallel to output beam OB.

In some embodiments, output beam splitter 16 may be configured as a beam combiner, receiving input beam portions arriving along man path MP and auxiliary path, and transmitting only a single output beam portion OB, thus not directing light portion along auxiliary path APn. The output beam splitter 16 may utilize a suitable coating, causing destructive interference conditions for light directing toward auxiliary path APn, while providing constructive interference conditions to light propagating along the output beam path OB.

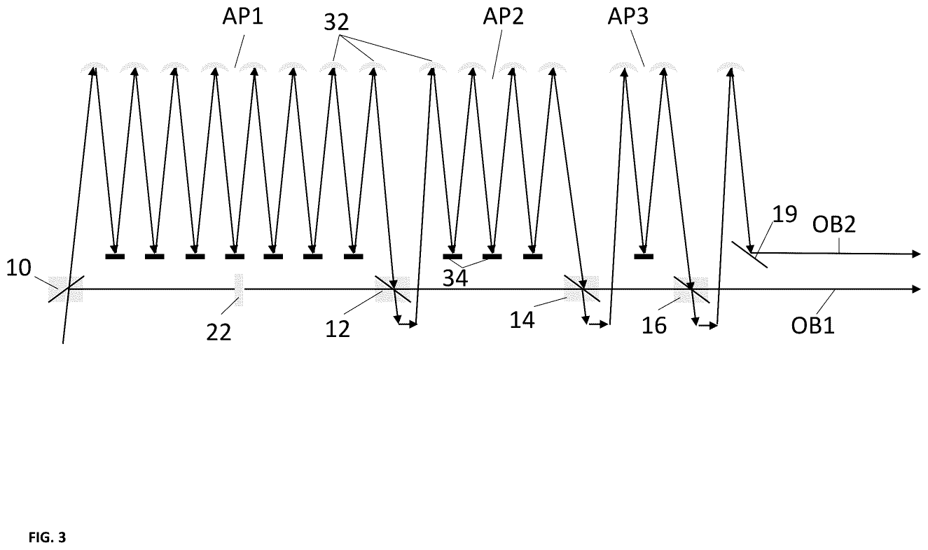

Generally, the pulse stretcher according to the present disclosure may utilize polarization independent beam splitters. However, in some embodiments, the input polarization beam splitter 10 may be a polarization beam splitter, while intermediate beam splitters 12 and 14, and output beam splitter 16 may be polarization independent beam splitters. Reference is made to FIG. 3 exemplifying an additional example of pulse stretcher according to some embodiments of the present disclosure. In this example, the pulse stretcher includes an input beam splitter 10 configured as a polarizing beam splitter having a selected polarizing axis, and a polarization rotator 22, such as a half waveplate. The pulse stretcher in this example may generally be configured to receive input beam having selected polarization state such as linear polarization aligned at 45° to polarizing axis of input beam splitter 10, circular polarization or other polarization states that can be separated into equal power in first and second orthogonal linear polarization orientations.

The pulse stretcher configuration exemplified in FIG. 3 is configured to provide output pulse train having selected polarization orientation, and may be associated with one or more polarization shifting elements, such as half waveplate, quarter waveplate, or others, to selectively generate output beam of any selected polarization.

Additionally, as illustrated in FIGS. 2 and 3, the selected number of auxiliary paths AP1 to APn may include a selected number of reflective surfaces 32 and 34, e.g., mirrors, for reflecting beam portions along the auxiliary paths to provide the selected length of optical path, and selected time delay between pulse components. The reflective surfaces may include one or more spherical reflective surfaces 32 having selected curvature radius, selected to maintain at least one of divergence angle and width of the beams, to provide substantially similar beam profile of the different pulses of the output beam. As shown in FIG. 3 the auxiliary paths may utilize a combination of flat 34 and curved 32 reflective surfaces in accordance with optical design to maintain divergence angle and/or width of the output beam OB.

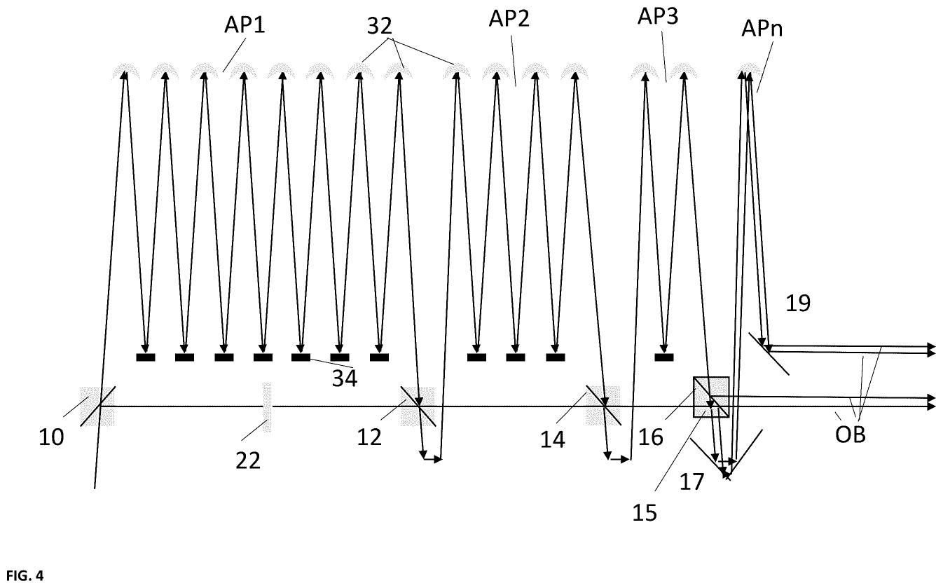

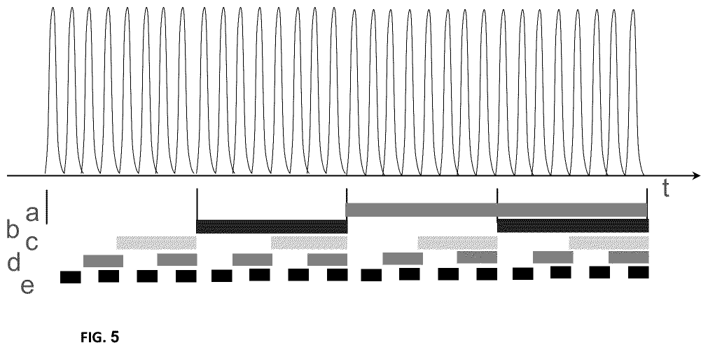

An additional configuration of the pulse stretcher according to some embodiments of the present disclosure is exemplified in FIG. 4. Here the pulse stretcher is exemplified having similar configuration as illustrated in FIG. 3, while the output beam splitter 16 is mounted on a moveable platform 15. Moveable platform 15 may be used for changing position of output beam splitter 16 along at least one axis and may be selectively used for adjusting location of output beam splitter 16 along two or three axes. Additionally, FIG. 4 exemplifies an additional reflective surface 17, e.g., configured as a retroreflector, positioned to align second portion of beam transmitted by output beam splitter 16. The additional reflective surface 17 is configured to direct the second beam portion resulting from input beam portion arriving the output beam splitter 16 from the auxiliary path AP3 and transmitted through the beam splitter 16, and second beam portion resulting from input beam portion arriving the output beam splitter 16 along the main path and reflected by beam splitter 16. Due to variations in location of the beam splitter 16, these output beam portions are not overlapping. Thus, the additional reflective surface 17 may be configured as retroreflector to direct the second output beam portion toward the Auxiliary path APn independent of exact transverse location of the second output beam portions.

This situation is similar for first output beam portions, being output from the output beam splitter 16. Accordingly, as a result of shift in position of the output beam splitter 16, such that beam portions propagating along main path MP and auxiliary path AP3 imping on spatially separated spots of the beam splitter 16, the output beam OB may be formed of two to four generally parallel output beams. This configuration may be used to enhance illumination etendue, but enhancing output beam transverse cross-section, while generally maintaining divergence angle and/or width of the output beams.

It should be noted that generally, any one of the selected number of beam splitters may be placed on a moveable platform, providing that lateral shift in location of the beam splitter shifted beam portions to generate one or more non-overlapping output beams. Selection of one or more beam splitters positioned on a moveable platform may determine power ratio between the non-overlapping beam portions in accordance with number of beam splitters upstream or downstream of the moveable platform.

The underlaying effect of the pulse stretcher 100 according to some embodiments of the present disclosure is illustrated in FIG. 5. Generally, and input short pulse enters the pulse stretcher, and is initially split by first input beam splitter 10. The input pulse is divided into two portions, first portion propagates along main path MP, and second portion propagated along first auxiliary path AP1 having a selected optical path/length L. Due to the variation in length between the main path MP and auxiliary path AP1, the first portion reaches second beam splitter 12 before the second portion that propagated along the auxiliary path as exemplified in row a.

The second beam splitter 12 this received two input pulses, first input pulse arrives from the main path MP, and is split into first portion that propagated along the main path MP, and second portion propagating along second auxiliary path AP2. After selected time of the order of L/c a second portion arrives at the second beam splitter 12 and is also split into a first portion that propagated along the main path MP, and second portion propagating along second auxiliary path AP3 as exemplified in row b.

Rows c, d, and e in FIG. 5 further illustrate operation of the following beam splitters, indicating that each beam splitter received a first input pulse propagating along the main path MP and splits it to a first portion propagating along the main path and a second portion propagating along the respective auxiliary path. After the first pulse, the beam splitter receives a second pulse propagating along the auxiliary path, the second pulse is again split into a first portion propagating along the main path and a second portion propagating along the respective auxiliary path. The later beam splitter also receives further beam portions associated with various paths possible for the beam portions, splitting each beam portion and increasing the number of pulses.

As indicated above, the beam splitters are generally selected to be 50/50 beam splitters. However, to overcome potential loss in illumination power due to the plurality of reflections of beam portions propagating along the auxiliary paths, the beam splitters may direct increased illumination power toward the auxiliary path. For example, the beam splitters may be e.g., 60/40 beam splitters, or other ratio selected in accordance with loss level along the auxiliary path, where the higher power is transmitted toward the auxiliary path.

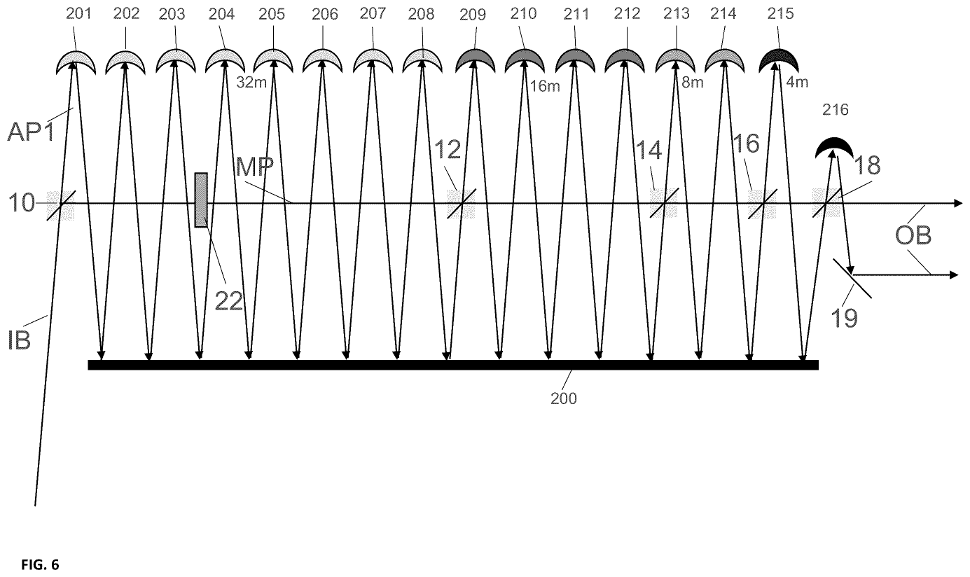

An additional exemplary configuration of the pulse stretcher according to some embodiments is illustrated in FIG. 6. FIG. 6 illustrates a pulse stretcher configured for folding the plurality of auxiliary paths between an arrangement of spherical reflectors 201 to 216 and a flat reflector 200 common to the auxiliary paths. More specifically, input pulse IB may be input to the pulse stretcher 100. The input pulse IB is split by the beam splitters 10 to 16 in a cascade manner to generate a plurality of pulse portions propagating along the main and/or selected number of auxiliary paths. The spherical mirrors 201 to 216 are positioned to for a plurality of auxiliary paths. More specifically, in this example, mirrors 201 to 208 relate to first auxiliary path AP1 and defining length of L=32 m for auxiliary path AP1. Mirrors 209 to 212 relate to second auxiliary path AP2 and defining its length to be 16 m=L/2. The third auxiliary path is defined by mirrors 213 and 214 and has length of 8 m=L/4. Mirror 215 defines the fourth auxiliary path having length of 4 m=L/8. Finally, mirrors 216 and 19 define a fifth auxiliary path having length of 2 m=L/16.

The pulse stretcher may utilize an input polarization beam splitter 10 and a polarization rotator 22, such as half wavelength plate, located between the first beam splitter 10 and the second beam splitter 12, to provide polarized output beam based on input pulse having suitable polarization orientation at the input.

As indicated above, location of output reflective element 19 enables adjustment of spatial arrangement of the output beam OB, enabling to determine etendue of the output beam in accordance with desired illumination requirements. Similarly, output beam splitter, 18 in this example, may be placed on a moving mount, configured to be selectively shifted along one or more directions. Adjustment of location of the output beam splitter is illustrated in FIG. 4, and may be used to provide selected tailoring of output beam parameters such as beam width, etendue etc.

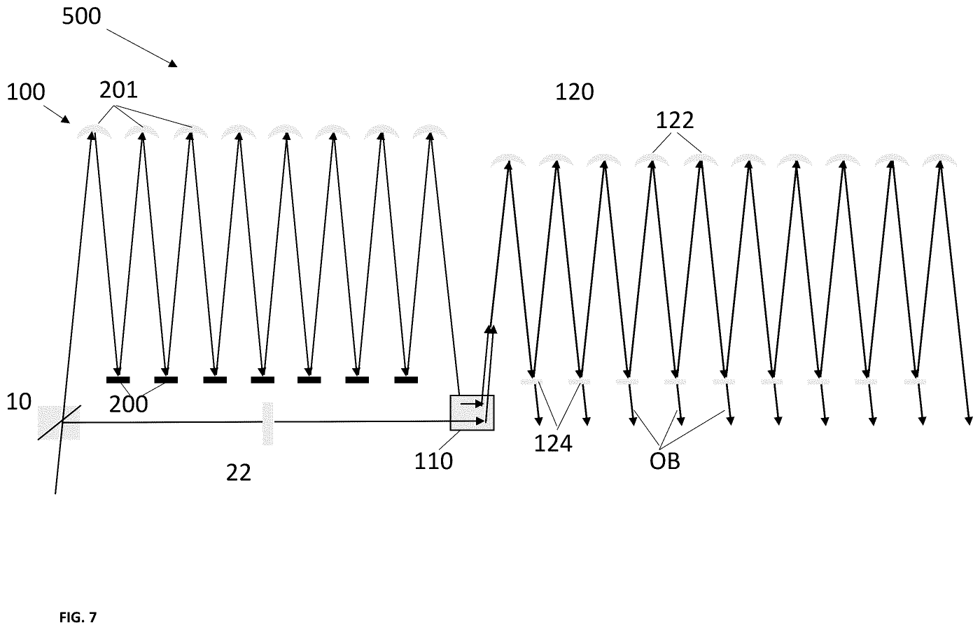

Generally, the pulse stretcher of the present disclosure provides conversion of input pulses into output pulse train having selected time delay between the pulses and having generally similar pulse amplitude. The pulse stretcher of the present disclosure may be used in combination with one or more conventional pulse stretcher units. FIG. 7 exemplifies a pulse stretcher system 500 formed using a first pulse stretcher 100 configured as described above, and a second pulse stretcher 120 configured to receive input optical signal and generate output signal formed of a plurality of spatially separated optical beams. The first pulse stretcher 100 of the system 500 is configured as described herein, to receive input signal having one or more short pulses, and to generate output signal formed of a plurality of pulses, being temporally separated, or slightly temporally overlapping. The output beam of the first pulse stretcher 100 having temporal structure formed of a plurality of pulses, is used as input beam to a second pulse stretcher unit 120. The second pulse stretcher unit 120 is configured to receive an input beam and generate a spatial arrangement of output beams OB. In this example, second pulse stretcher 120 is configured by a plurality of reflective surfaces or mirrors, and an arrangement of one or more partially reflecting surface. With each reflection of electromagnetic radiation beams through the second pulse stretcher, a portion of the reflected beam is coupled out to generate output beam OB. This configuration may be used to expand an input short pulse in temporal domain as well as in spatial domain. More specifically, an input short pulse may be expanded using the first pulse stretcher unit 100 into a plurality of pulses, having selected time separation between them and generally similar intensity. The output beam having a plurality of pulses (e.g., pulse train) is further split using the second pulse stretcher 120 to output beam that is stretched in space to provide wide output beam OB. The spatial stretching may provide a selected spatial distance between portions of the output beam OB, providing the different spatial portions completely separated, or partially overlapping between them.

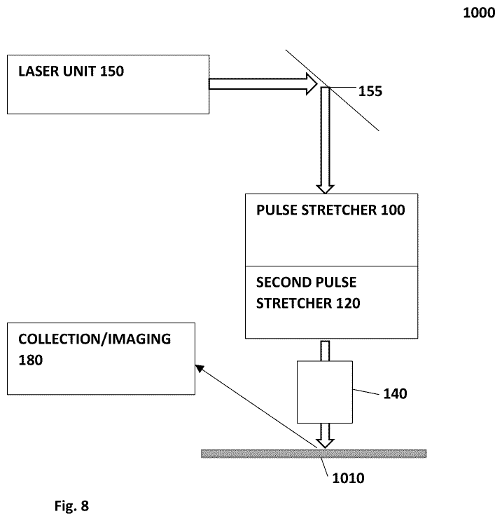

The pulse stretcher unit 100 of the present disclosure may be used for various illumination and imaging purposes. FIG. 8 exemplifies an optical inspection system configured for inspection of a sample 1010. The system includes a light source, e.g., laser, 150 providing radiation beam of a selected wavelength range. Generally, due to the selected wavelength range, and requirements of construction of laser system for emitting the selected wavelength range, laser output beam is formed of a plurality of short pulses. Output of the laser unit 150 is directed using an optical arrangement, exemplified by reflective surface 155, to input port of pulse stretcher 100. Pulse stretcher 100 is configured as described above and is operable to receive the input short pulse and stretch the input pulse in time to generate output beam formed of a plurality of pulses, having substantially similar amplitude. Output beam of the first pulse stretcher 100 may be directed to a second pulse stretcher 120 if used, to provide spatial stretching of the output beam. Second pulse stretcher may be used in accordance with desired beam characteristics, and in some embodiments, the system may utilize first pulse stretcher 100 only.

Stretched output beam may be directed to illuminate a sample 1010 using an optical arrangement 140. Optical arrangement 140 may include one or more lenses and may be configured to provide desired illumination pattern onto sample 1010. The radiation impinging on the sample is further directed to a collection/imaging unit 180 for generating output data indicative of radiation interaction with the sample 1010. The collected data is further used to determine structure of the sample 1010. In some inspection systems the collection/imaging unit 180 may share one or more common optical elements with the optical arrangement 140. Such one or more common optical elements may include one or more lenses, grating, filters, and/or one or more beam splitting optical elements configured to direct illumination onto the sample 1010 and collected illumination to one or more detectors of the collection/imaging unit 180.

Generally, inspection system 1000 may be used for inspection of semiconductor wafer and/or mask or reticle suitable for use on manufacturing of semiconductor devices. The inspection system may utilize a selected wavelength range and may for example use short ultraviolet illumination. The existing typical laser units operable with such short wavelength provide short pulse output. Accordingly, the use of pulse stretcher enables tailoring of illumination beam characteristics on top of limitations due to available laser units. The pulse stretcher described herein can lengthen pulse duration by generating a plurality of pulses having substantially similar amplitude, and desired delay between them, where the delay can be determined by minimal relative length of the auxiliary path with respect to respective main path. It should be understood that the various auxiliary paths of the pulse stretcher may have any desired order. Accordingly, although being exemplified hereinabove in order according to length, the order of auxiliary paths based on length may be random or any other selected order.

Thus, the present disclosure provides a pulse stretcher configuration providing temporal stretching, and optionally providing also spatial stretching of the pulse. The pulse stretcher unit is formed of a selected number of beam splitters, arranged along a main path of light propagation. The selected number of pulse splitters comprise an input beam splitter, an output beam splitter, and one or more intermediate beam splitters. Each one of the beam splitters is configured to receive input beam and split the input beam to first portion propagating along main path, and to second portion propagating along the respective auxiliary path, thereby varying optical path of the beam components to generate relative delay between beam portions. More specifically, the intermediate beam splitters receive input beam portion propagating along the main path as well as along the auxiliary path, and split each of the received beam portion, thereby doubling number of pulses in the output pulse train.

It is to be noted that the various features described in the various embodiments can be combined according to all possible technical combinations.

It is to be understood that the invention is not limited in its application to the details set forth in the description contained herein or illustrated in the drawings. The invention is capable of other embodiments and of being practiced and carried out in various ways. Hence, it is to be understood that the phraseology and terminology employed herein are for the purpose of description and should not be regarded as limiting.

As such, those skilled in the art will appreciate that the conception upon which this disclosure is based can readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

1. A pulse stretcher unit comprising:
a selected number of beam splitters arranged along a selected main path and comprising an input beam splitter, an output beam splitter and one or more intermediate beam splitters, and
an arrangement of light reflecting surfaces defining a selected number of n auxiliary paths extending between said selected number of beam splitters; wherein
(a) said input beam splitter is configured to receive an input beam and to direct a first portion of the beam along said selected main path and a second portion of the beam along a first auxiliary path;
(b) said output beam splitter is configured to receive first input beam portion propagating along said selected main path and a second input beam portion propagating along an n'th auxiliary path, and to provide at least one output beam propagating along said selected main path; and
(c) each one or more intermediate beams splitters is configured to receive a first input beam portion propagating along said selected main path and a second input beam portion propagating along an i'th auxiliary path, and to provide a first portion of output beam propagating along said selected main path and a second portion of output beam propagating along a respective i+1 auxiliary path; and wherein
lengths of said auxiliary paths follow approximately a series of the form L/2^{k} for k=0, 1, 2, where L is a selected length of an auxiliary path.

2. The pulse stretcher unit of claim 1, wherein the lengths of said auxiliary paths follow the form L/2^{k} for k=0, 1, 2, where L is a selected length of an auxiliary path up to 10% length variation.

3. The pulse stretcher of claim 1, wherein length of said auxiliary path being larger than length of portion of said selected main path between consecutive beam splitters.

4. The pulse stretcher unit of claim 1, further comprising an output reflecting surface, wherein said output beam splitter provides a portion of output beam to propagate along said selected main path and a second portion of output beam to propagate along an output auxiliary path, said output reflecting surface is positioned to direct said second portion of output beam to propagate along a selected auxiliary output path.

5. The pulse stretcher unit of claim 1, wherein said selected number of beam splitters comprise one or more beam splitters mounted on a moveable platform, moveable along at least one axis perpendicular to said selected main path, enabling output beam in the form of two parallel output beams.

6. The pulse stretcher unit of claim 1, wherein said output beam splitter is mounted on a moveable platform, moveable along at least one axis perpendicular to said selected main path, enabling output beam in the form of two parallel output beams.

7. The pulse stretcher unit of claim 1, wherein said arrangement of light reflecting surfaces comprise a selected number of curved reflective surfaces configured to focus beam impinging thereof to maintain at least one of beam divergence angle and beam width.

8. The pulse stretcher unit of claim 1, wherein said selected number of beam splitters consists of polarization independent beam splitters.

9. The pulse stretcher of claim 1, wherein said input beam splitter is a polarization beam splitter and said output beam splitter and one or more intermediate beam splitters are polarization independent beam splitters.

10. The pulse stretcher unit of claim 9, further comprising a polarization rotation plate positioned in said selected main path between said input beam splitter and a consecutive beam splitter.

11. The pulse stretcher unit of claim 9, further comprising a polarization rotation plate positioned in said auxiliary path between said input beam splitter and a consecutive beam splitter.

12. The pulse stretcher unit of claim 1, wherein said selected number of beam splitters comprise polarization independent beam splitters.

13. The pulse stretcher unit of claim 1, wherein said selected number of beam splitters consists of beam splitter configured to split input beams with a power ratio between 0.4:0.6 and 0.6:0.4.

14. The pulse stretcher unit of claim 1, wherein said arrangement of beam splitter define one or more auxiliary paths and wherein said one or more auxiliary paths are being folded by one or more reflecting surfaces arranged to cause radiation to be reflected back and front between the reflective surfaces through the auxiliary path.

15. The pulse stretcher unit of claim 1, wherein at least one auxiliary path is formed of a plurality of spherical mirrors and a common flat mirror arranged such that radiation beam is reflected between said spherical mirrors and said flat mirror for a selected number of times.

16. The pulse stretcher unit of claim 1, operable in ultraviolet wavelength range.

17. A pulse stretching system comprising at least one first pulse stretcher unit and at least one second pulse stretcher unit; said at least one first pulse stretcher unit comprises:
a selected number of beam splitters arranged along a selected main path and comprising an input beam splitter, an output beam splitter and one or more intermediate beam splitters, and
an arrangement of light reflecting surfaces defining a selected number of n auxiliary paths extending between said selected number of beam splitters; wherein
(a) said input beam splitter is configured to receive an input beam and to direct a first portion of the beam along said selected main path and a second portion of the beam along a first auxiliary path;
(b) said output beam splitter is configured to receive first input beam portion propagating along said selected main path and a second input beam portion propagating along an n'th auxiliary path, and to provide at least one output beam propagating along said selected main path; and
(c) each one or more intermediate beams splitters is configured to receive a first input beam portion propagating along said selected main path and a second input beam portion propagating along an i'th auxiliary path, and to provide a first portion of output beam propagating along said selected main path and a second portion of output beam propagating along a respective i+1 auxiliary path; wherein
lengths of said auxiliary paths follow approximately a series of the form L/2^{k} for k=0, 1, 2, where L is a selected length of an auxiliary path; and wherein
said at least one second pulse stretcher unit is placed downstream of said at least one first pulse stretcher unit, such that output beam of said at least one first pulse stretcher unit is input beam to said at least one second pulse stretcher unit.

18. The pulse stretcher system of claim 17, wherein said at least one second pulse stretcher is configured to stretch input beam at least partially in spatial domain.

19. An inspection system comprising a light source unit, a pulse stretcher unit, and a collection unit for collecting illumination signal from a sample, wherein said pulse stretcher unit is configured to receive input illumination beam from said light source unit and to split one or more pulses of said input illumination beam into a plurality of pulses having selected temporal separation between them and having substantially equal amplitude, and to direct output beam comprising said plurality of pulses to illuminate the sample.

20. The inspection system of claim 19, wherein said pulse stretcher unit comprises a selected number of beam splitters arranged along a selected main path and comprising an input beam splitter, an output beam splitter and one or more intermediate beam splitters, and
an arrangement of light reflecting surfaces defining a selected number of n auxiliary paths extending between said selected number of beam splitters; wherein
(a) said input beam splitter is configured to receive an input beam and to direct a first portion of the beam along said selected main path and a second portion of the beam along a selected first auxiliary path;
(b) said output beam splitter is configured to receive first input beam portion propagating along said selected main path and a second input beam portion propagating along an n'th auxiliary path, and to provide at least one output beam propagating along said selected main path; and
(c) each one or more intermediate beams splitters is configured to receive a first input beam portion propagating along said selected main path and a second input beam portion propagating along an i'th auxiliary path, and to provide a first portion of output beam propagating along said selected main path and a second portion of output beam propagating along a respective i+1 auxiliary path; wherein
lengths of said auxiliary paths follow approximately a series of the form L/2^{k} for k=0, 1, 2, where L is a selected length of an auxiliary path.
